(19) United States
(12) Patent Application Publication
(10) Pub. No.: US 2012/0049251 A1
(43) Pub. Date: Mar. 1, 2012

(54) SEMICONDUCTOR DEVICE

(75) Inventor: KAZUAKI TAKESAKO, TOKYO (JP)

(73) Assignee: ELPIDA MEMORY, INC, TOKYO (JP)

(21) Appl. No.: 13/192,496

(22) Filed: Jul. 28, 2011

(30) Foreign Application Priority Data
Aug. 26, 2010 (JP) 2010-189777

(51) Int. Cl. H01L 29/78; H01L 29/06

(52) U.S. Cl. 257/288; 257/622; 257/E29.005; 257/E29.255

(57) ABSTRACT

A semiconductor device may include, but is not limited to: a semiconductor substrate; a first insulating film; and a first semiconductor film. The semiconductor substrate has a groove defining a first portion of the semiconductor substrate. The first portion extends upward. The first insulating film fills the groove. The first insulating film has a recess adjacent to a side surface of the first portion. The first semiconductor film contacts an upper surface and the side surface of the first portion.

### BACKGROUND OF THE INVENTION

1. Field of the Invention

The present invention relates to a semiconductor device.

Priority is claimed on Japanese Patent Application No. 2010-189777, filed Aug. 26, 2010, the content of which is incorporated herein by reference.

2. Description of the Related Art

Generally, LSI (large scale integrated) circuits are used in main parts of computers and electronic devices. In an LSI circuit, multiple MOS transistors, resistors, and the like are integrated on a chip. Particularly, elements, such as DRAM (dynamic random access memory), have been rapidly miniaturized.

Regarding semiconductor devices, such as DRAM, a raised source and/or drain structure has been known, in which a silicon film is formed over an active region of a semiconductor substrate as a source and/or drain electrode of a MOS transistor.

As a general method of forming such a silicon film, a selective epitaxial growth is carried out while an upper surface (silicon surface) of the active region is exposed, and thus a mono-crystalline silicon film is formed (see, for example, Japanese Patent Laid-Open Publication No. 2008-130756).

Regarding a memory cell region and the like, in which multiple MOS transistors need to be densely arranged, the area of active regions decreases further with the miniaturization of semiconductor devices.

For the above reason, when a silicon film is formed over an active region in a memory cell, the area of an exposed silicon surface is too small to properly carry out selective epitaxial growth, thereby resulting in insufficient growth of a silicon film.

Among memory cells, there is a variation in the area of an exposed silicon surface, which is caused by misalignment upon formation of a gate electrode. For this reason, if selective epitaxial growth is carried out for a longer time than necessary to form a sufficient amount of a silicon film, the vertical size of the silicon film increases in a memory cell in which the area of an exposed silicon surface is relatively large, and the silicon film grows in the lateral direction. Consequently, short-circuit between two adjacent memory cells occurs through the silicon film.

Thus, in the case of the semiconductor device of the related art, it has been difficult to reduce the number of memory cells in which a silicon film is not sufficiently formed while preventing short-circuit between two adjacent memory cells. For this reason, predetermined operation characteristics cannot be obtained, thereby decreasing the manufacturing yield.

### SUMMARY

In one embodiment, a semiconductor device may include, but is not limited to: a semiconductor substrate; a first insulating film; and a first semiconductor film. The semiconductor substrate has a groove defining a first portion of the semiconductor substrate. The first portion extends upward. The first insulating film fills the groove. The first insulating film has a recess adjacent to a side surface of the first portion. The first semiconductor film contacts an upper surface and the side surface of the first portion.

In another embodiment, a semiconductor device may include, but is not limited to: a semiconductor substrate; a gate electrode structure; a first semiconductor film; and a second semiconductor film. The semiconductor substrate has a first portion extending upward. The gate electrode structure is positioned over the first portion. The first semiconductor film is adjacent to the gate electrode. The first semiconductor film contacts an upper surface of the first portion. The second semiconductor film is adjacent to the gate electrode. The first semiconductor film is separated from the second semiconductor film. The second semiconductor film contacts the upper surface and a side surface of the first portion.

In another embodiment, a semiconductor device may include, but is not limited to: a semiconductor substrate; an insulating film; a wiring structure; and a semiconductor film. The semiconductor substrate has a first portion extending upward. The insulating film is adjacent to the first portion. A top level of the insulating film is substantially equal to a top level of the first portion. The insulating film has a recess adjacent to a side surface of the first portion. A wiring structure is positioned over the insulating film. The recess is positioned between the first portion and the insulating film in plan view. The semiconductor film is adjacent to the wiring structure. The semiconductor film contacts an upper surface and the side surface of the first portion. The semiconductor film fills the recess.

### BRIEF DESCRIPTION OF THE DRAWINGS

The above features and advantages of the present invention will be more apparent from the following description of certain preferred embodiments taken in conjunction with the accompanying drawings, in which:

FIGS. 1A and 1B are plan views illustrating a semiconductor device according to a first embodiment of the present invention;

FIG. 2 is a cross-sectional view illustrating the semiconductor device of the first embodiment;

FIGS. 3 and 4 are plan views illustrating the semiconductor device of the first embodiment;

FIGS. 5A to 14B are cross-sectional and plan views illustrating a process flow indicative of a method of manufacturing the semiconductor device of the first embodiment;

FIGS. 15A and 15B are cross-sectional views illustrating a modified example of the semiconductor device of the first embodiment;

FIGS. 16A and 16B are cross-sectional views illustrating a semiconductor device of a second embodiment of the present invention; and

FIGS. 17A to 22B are cross-sectional and plan views illustrating a process flow indicative of a method of manufacturing the semiconductor device of the second embodiment.

### DETAILED DESCRIPTION OF THE PREFERRED EMBODIMENTS

The present invention will now be described herein with reference to illustrative embodiments. The accompanying drawings explain a semiconductor device and a method of manufacturing the semiconductor device in the embodiments. The size, the thickness, and the like of each illustrated portion might be different from those of each portion of an actual semiconductor device.

Those skilled in the art will recognize that many alternative embodiments can be accomplished using the teachings of the present invention and that the present invention is not limited to the embodiments illustrated herein for explanatory purposes.

### First Embodiment

Hereinafter, a semiconductor device 1 and a method of manufacturing the same according to a first embodiment of the present invention are explained. Hereinafter, it is assumed that the semiconductor device 1 functions as DRAM. However, the present invention is not limited to the DRAM, and is applicable to a semiconductor device including memory cells each including a memory element for storing data and a selection transistor, such as ReRAM (resistance random access memory), PRAM (phase change random access memory), and MRAM (magnetoresistive random access memory).

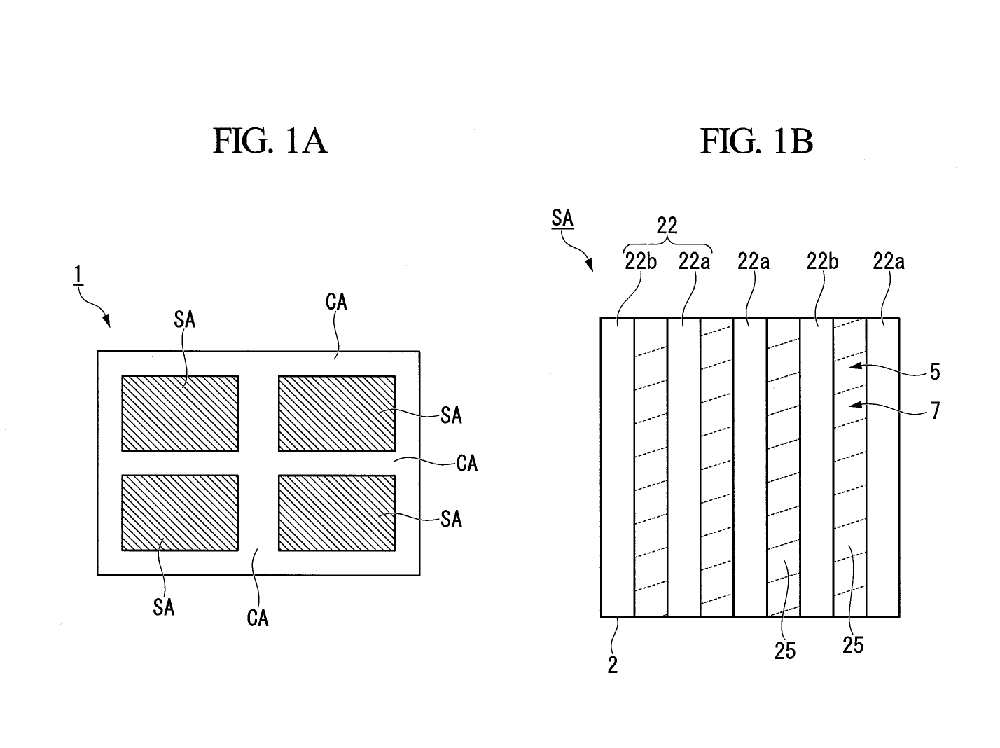

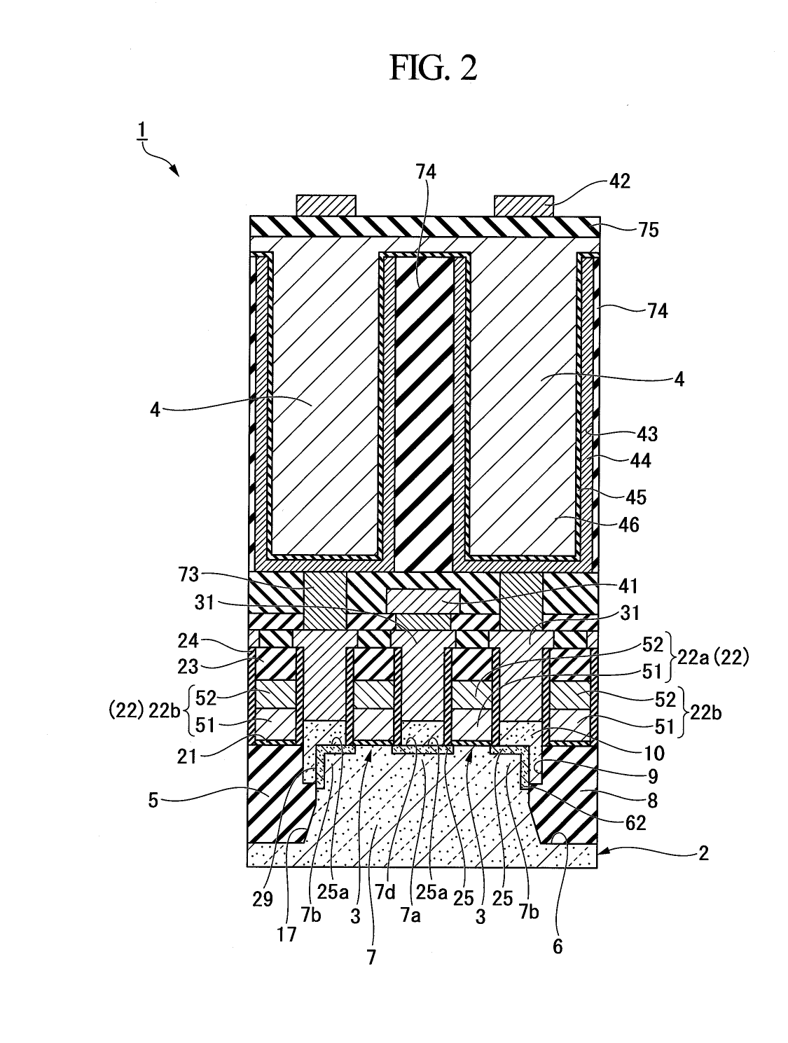

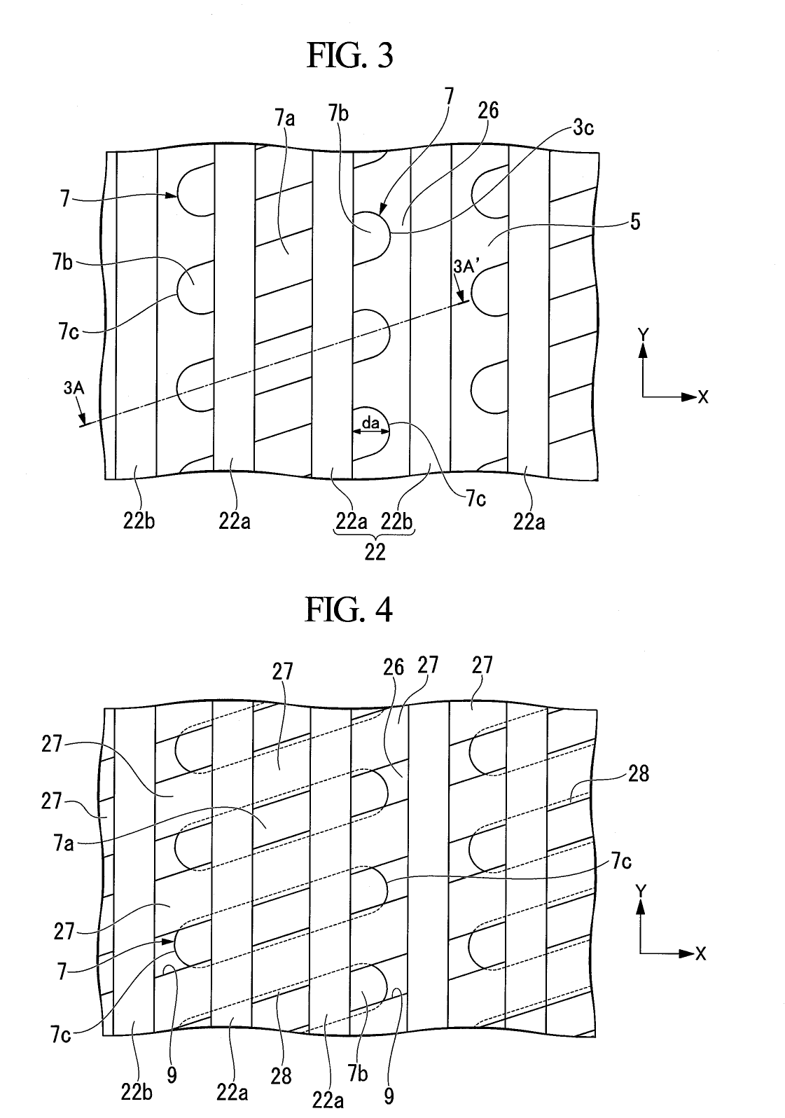

Hereinafter, the semiconductor device 1 of the first embodiment is explained in detail. FIG. 1A is a plan view illustrating the semiconductor device 1. FIG. 1B is an enlarged view illustrating part of the memory cell region SA. FIG. 2 is a cross-sectional view taken along line 3A-3A′ shown in FIG. 3 and illustrating the semiconductor device 1. FIGS. 3 and 4 are plan views illustrating the semiconductor device 1.

As shown in FIG. 2, the semiconductor device 1 includes: a semiconductor substrate 2; a selection transistor 3 over the semiconductor substrate 2; and a capacitor 4 over the transistor 3.

As shown in FIG. 1A, the semiconductor substrate 2 has memory cell regions SA and a peripheral circuit region CA surrounding the memory cell regions SA. A semiconductor chip is provided over the memory cell region SA. A circuit block, such as a sense amplifier circuit, a decoder circuit, and an input/output circuit, is provided over the peripheral circuit region CA. The number and layout of memory cell regions SA are not limited to FIG. 1A.

A bit wire 41 and a word wire 22a are provided over the memory cell region SA. A memory cell is provided at an intersection of the bit wire 41 and the word wire 22a. The memory cells over the memory cell region SA are arranged in a matrix. The memory cell includes: the selection transistor 3; and the capacitor 4 electrically coupled to one of source and/or drain portions 25 of the transistor 3. In the case of DRAM, the capacitor 4 functions as a memory element that stores data.

As shown in FIG. 1B, multiple shallow trenches 6, which extend in one direction, are formed in the memory cell region SA of the semiconductor substrate 2. The shallow trenches 6 are filled with device isolation films 8 which are insulating films. Thus, multiple device isolation regions 5 called STI (shallow trench isolation), and multiple active regions 7 defined by the device isolation regions 5 are alternately arranged in a striped manner.

Multiple word wires 22a and dummy word wires 22b are provided in a striped manner over the memory cell region SA so as to extend in a direction different from the extending direction of the device isolation regions 5 and the active regions 7. In the case of FIG. 1B, every third line of the word wires is the dummy word wire 22b. The word wires 22a function as gate electrodes of the transistor 3.

As shown in FIG. 2, side surfaces of the shallow trenches 6 are equal to side surfaces 17 of the active regions 7. Recessed portions 9 are formed in the device isolation films 8, adjacent to the side surfaces 17 of the active regions 7. The recessed portions 9 are filled with a silicon film 10. The positions of the recessed portions 9 are explained later. Thus, the semiconductor substrate 2 has the active regions 7 isolated from one another by the device isolation regions 5.

FIG. 3 is a plan view illustrating part of the semiconductor device 1. The active regions 7 of the semiconductor substrate 2 are arranged at a predetermined interval and extend in one direction. Each of the active regions 7 has a reed shape. The arrangement of the active regions 7 is called 6F². However, the present invention is not limited thereto, and an arrangement following another rule may be used.

Hereinafter, the horizontal direction and the vertical direction shown in FIG. 3 are defined as an X-direction and a Y-direction, respectively. The direction in which the active regions 7 extend is defined as an extending direction. A direction perpendicular to the extending direction is defined as a perpendicular direction. The extending direction is not perpendicular to the Y direction, but crosses the Y direction in plan view.

As shown in FIG. 2, the word wires 22a and the dummy word wires 22b are provided over the semiconductor substrate 2. The word wires 22a function as gate electrodes. The dummy word wires 22b function as dummy electrodes. Hereinafter, the word wires 22a and the dummy word wires 22b are collectively called a word wiring layer 22.

A first insulating film 23 is provided over the word wiring layer 22. A sidewall 24 is provided so as to cover side surfaces of the word wiring layer 22. Source and/or drain portions 25 containing an impurity are formed in the active region 7 of the semiconductor substrate 2, adjacent to an upper surface 7d of the active region 7, at positions defined by self-alignment with respect to the word wire 22a.

As shown in FIG. 3, the word wires 22a extend in the Y direction so as to cross the active regions 7 and the device isolation regions 5 in plan view. The dummy word wires 22b extend in the Y-direction so as to cross only the device isolation regions 7 in plan view. The width of each word wiring layer 22 is set to be approximately F, where F denotes a value indicating design rule. The pitch of the word wiring layers 22 is approximately 2F.

Two word wires 22a extending in the Y-direction cross each active region 7 in plan view. Accordingly, each active region 7 is divided into three by the two word wires 22a in plan view. The center part of the divided portions is defined as an active region 7a. The two outer parts of the divided portions are defined as active regions 7b. The active regions 7a and 7b are electrically coupled to the bit wire 41 and the capacitor 4, respectively, as shown in FIG. 2.

The width of the active region 7 in the perpendicular direction is set to be approximately F. An interval of the active regions 7 in the perpendicular direction is also approximately F. An interval between two adjacent active regions 7 arranged in the extending direction is set to be larger than F. The length of the active region 7a in the extending direction is set to be approximately F. The length of the active region 7b in the extending direction is set to be smaller than F. Accordingly, there is space between an end portion 7c of the active region 7b and the dummy word wire 22b. This space is called an inter-wire region 26.

FIG. 4 is a plan view illustrating part of the semiconductor device 1, in which an illustration of the sidewall 24 is omitted. A third insulating film 27 is formed on a portion of the device isolation region 5, which is positioned between two adjacent active regions 7 arranged in the perpendicular direction and between two adjacent word wiring layers 22.

In other words, the third insulating film 27 intermittently extends in the extending direction between two adjacent active regions 7 arranged in the perpendicular direction, except where the word wiring layer 22 and the sidewall 24 are disposed. Accordingly, the third insulating film 27 has a parallelogram shape in plan view.

The width of the third insulating film 27 in the perpendicular direction is set to be larger than F. For this reason, the third insulating film 27 covers part of the active region 7. A region where the third insulating film 27 overlaps the active region 7 is called an overlap portion 28. The vertical thickness of the third insulating film 27 may be set to be larger or smaller than that of the silicon film 10.

As shown in FIG. 2, the silicon film 10 fills up the recessed portion 9 and covers part of the upper surface 25a of the source and/or drain portion 25. The silicon film 10 is an epitaxially-grown layer formed by selective epitaxial growth.

An upper part of the side surface 17 of the active region 7 is exposed to the recessed portion 9. The exposed upper part of the side surface 17 is called an exposed side surface 29. A source and/or drain portion 62 shown in FIG. 14A, which is an impurity diffusion region and is electrically coupled with the source and/or drain portion 25, is formed in the active region 7, adjacent to the exposed side surface 29.

As shown in FIG. 4, the recessed portion 9 is positioned between the word wire 22a and the dummy word wire 22b. Specifically, the recessed portion 9 is positioned in the inter-wire region 26 and between two adjacent third insulating films 27 arranged in the Y-direction. Accordingly, the recessed portion 9 is formed such that the side surfaces 17 of the two end portions 7c of the active region 7b are exposed. As shown in FIG. 2, the portion of the silicon film 10 covering the active region 7b and the portion of the silicon film 10 filling the recessed portion 9 are formed in an integrated manner.

A cell contact plug 31 is provided over the silicon film 10 covering the source and/or drain portion 25. The bit wire 41 is provided over the active region 7a so as to be electrically connected to the cell contact plug 31. A capacitor 4 is provided over the active region 7b so as to be electrically connected to the contact plug 31. A metal wiring layer 42 and the like are provided over the capacitor 4.

The capacitor 4 includes: a capacitor lower electrode 44 covering side and bottom surfaces of a capacitor contact hole 43; a capacitor insulating film 45 covering the capacitor lower electrode 44; and a capacitor upper electrode 46 covering the capacitor insulating film 46.

According to the semiconductor device 1 of the first embodiment, the silicon film 10 covers the upper side surface 17 and the upper surface 7d of the active region 7. Thereby, a sufficient amount of the silicon film 10 can be formed over the active region 7. In the case of the semiconductor device of the related art, the silicon film is formed while only an upper surface of the active region is exposed. For this reason, the area of an exposed silicon surface is small, thereby causing an insufficient amount of the silicon film. On the other hand, according to the first embodiment of the present invention, the silicon film 10 is formed while the upper surface 7d and the upper side surface 17 of the active region 7 are exposed. For this reason, the larger area of an exposed surface of the active region 7 can be secured, thereby enabling sufficient formation of the silicon film 10.

Additionally, the silicon film 10 extends upward from the active region 7. Therefore, a highly-concentrated impurity diffusion region can be formed, thereby enabling enhancement of driving performance of the transistor, a reduction in contact resistance of the contact plug, and application of a metal contact plug.

For example, even when a metal contact plug is used, and if a metal silicide layer is formed by reaction of a bottom surface of the metal contact plug with the silicon film, a high-concentrated impurity diffusion layer can be formed in the silicon film 10, thereby preventing degradation of the transistor characteristics.

Further, the third insulating film 27 is provided over the device isolation region 5 between two adjacent active regions 7 arranged in the perpendicular direction, thereby preventing short-circuit of the silicon films 10 between two adjacent active regions 7 arranged in the perpendicular direction.

Hereinafter, a method of manufacturing the semiconductor device 1 according to the first embodiment is explained in detail. The method of the first embodiment includes: a process of forming the active regions 7; a process of forming the word wires 22; a process of forming the impurity diffusion regions 25; a process of forming the second insulating films 53; a process of forming a mask; a process of forming the third insulating films 27; a process of partially removing the device isolation film 5; a process of removing the mask; a process of forming the silicon film 10; a process of introducing an impurity; a process of diffusing the impurity; a process of forming a contact plug; a process of forming the bit wire 41; and a process of forming the capacitor 4.

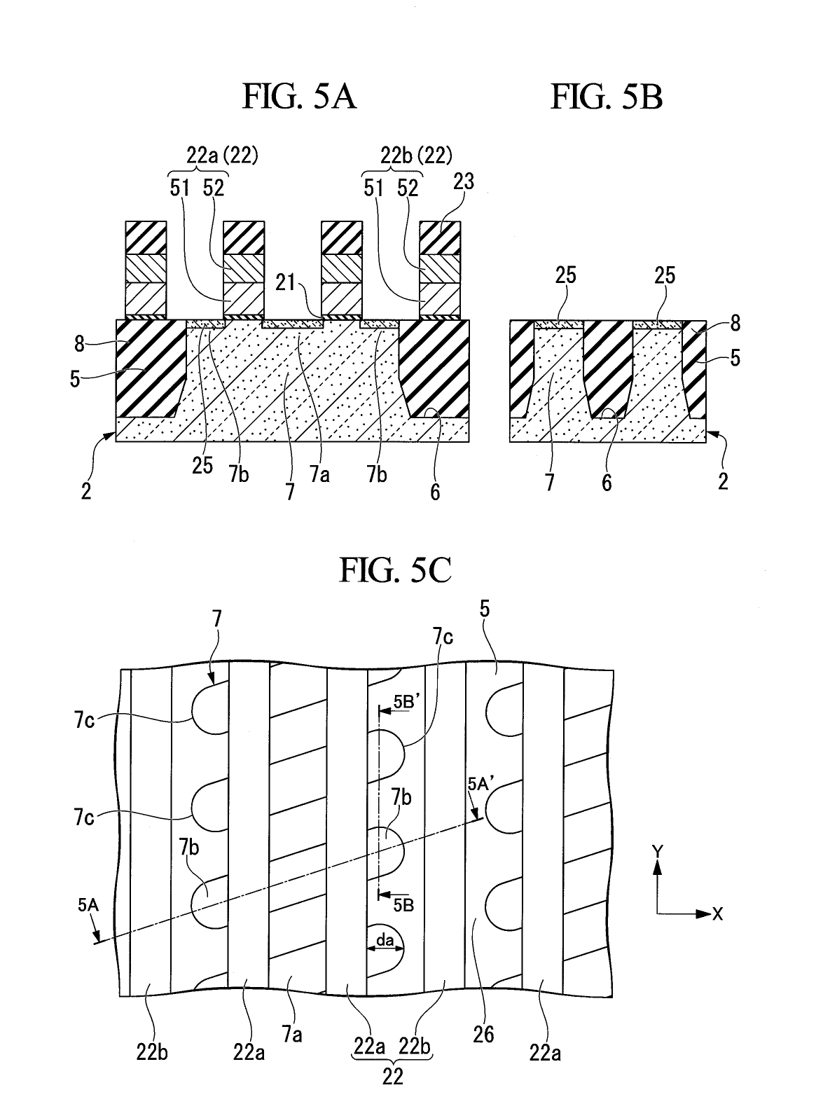

FIGS. 5A to 14A and FIGS. 5B to 14B are cross-sectional views illustrating a process flow indicative of a method of manufacturing the semiconductor device 1 of the first embodiment. FIGS. 5C, and 7C to 12C are plan views illustrating the process flow.

FIG. 5A is a cross-sectional view taken along line 5A-5A′ shown in FIG. 5C. FIG. 5B is a cross-sectional view taken along line 5B-5B′ shown in FIG. 5C. Similar applies to other drawing sets.

In the first process of forming the active region 7, the shallow trenches (grooves) 6 are formed in the semiconductor substrate 2, as shown in FIGS. 5A and 5B. The shallow trenches 6 are basis for forming the device isolation regions 5. The shallow trenches 6 define the active regions 7 in the semiconductor substrate 2.

Then, the shallow trenches 6 are filled with the device isolation film (insulating film) 8 to form the device isolation regions 5 having the STI structure. Thus, the active regions 7 are insulated from one another by the device isolation regions 5.

The active regions 7 are formed in a surface region of the semiconductor substrate 2. As shown in FIG. 5C, each active region 7 has a reed shape. The active regions 7 extend in the extending direction and are arranged at a predetermined interval.

As the semiconductor substrate 2, for example, a p-type silicon semiconductor substrate may be used. The material of the semiconductor substrate 2 is not limited thereto. For example, a semiconductor substrate containing germanium may be used.

An HDP-CVD (high-density plasma chemical vapor deposition) method may be used to form the device isolation film 8. As a material of the device isolation film 8, for example, a silicon oxide (SiO₂) film may be used. As a silicon oxide film, a coating insulating film, such as an SOD film, may be used. However, the material of the device isolation film 8 is not limited thereto. Another material may be used as long as the etching selectivity thereof with respect to the materials of the semiconductor substrate 2 and an insulating film 53 that will be explained later is adequate.

In the next process of forming the word wires 22, a gate insulating film 21, a gate silicon film 51, a gate high-melting point metal film 52, and a first insulting film 23 are sequentially formed over the semiconductor substrate 2, as shown in FIG. 5A. Then, the word wiring layer 22 including the gate silicon film 51 and the gate high-melting point metal film 52 is formed by photolithography and dry-etching processes. As the first insulating film 23, for example, a silicon nitride (Si₃N₄) film may be used.

The word wiring layer 22 extends in the Y-direction as shown in FIG. 5C. The word wiring layer 22 includes the word wire 22a and the dummy word wire 22b. The word wire 22a crosses the active region 7 in plan view, and functions as the gate electrode 15. The dummy word wire 22b is provided over the device isolation region 5, and extends between two adjacent active regions 7 without crossing the active region 7. The dummy word wire 22b functions as a dummy electrode. The dummy electrode is provided for maintaining the regularity of pattern arrangement when patterning the gate electrode 15 and thereby enhancing the precision of the patterning process.

The width of the each word wiring layer 22 in the X-direction is set to be approximately F. The interval between two adjacent word wiring layers 22 in the X-direction is set to be approximately F. The pitch of the word wiring layers 22 is set to be approximately 2F.

Two word wires 22a cross one active region 7 in plan view, and thus the active region 7 is divided into three parts. The center part of the divided parts is denoted as the active region 7a. The two other side parts of the divided parts are denoted as active regions 7b. The active region 7a and the active region 7b are electrically coupled to the bit wire 41 and the capacitor 4, respectively, as will be explained later.

To form the active regions 7, a photolithography process is carried out to form a resist pattern, and then an exposure process is carried out. In the first embodiment, as a mask design, the width of the active region 7 in the perpendicular direction is set to be approximately F. The interval between two adjacent active regions 7 arranged in the perpendicular direction is set to be approximately F. The length of the active region 7a and the length of the active region 7b in the extending direction are equally set to be approximately F.

In the exposure process, exposing light illuminates the both end portions 7c of the active region 7 in three different directions. For this reason, the length of the resist pattern in the extending direction becomes shorter than the mask designed size.

Consequently, the length da between the outer edge of the word wire 22a and the end portion 7c of the active region 7b becomes shorter than the mask designed size F. Accordingly, there becomes space between the end portion 7c of the active region 7b and the dummy word wire 22b. Thus, an upper surface of the device isolation region 5 is exposed in part. The space between the active region 7 and the dummy word wire 22b is called the inter-wire region 26. When the width of the dummy word wire 22b is shorter than F, the width of the inter-wire region 26 becomes longer.

In the next process of forming the impurity diffusion region 25, an impurity is introduced into the active region 7 with the first insulating film 23 as a mask to form the source and/or drain portion (impurity diffusion region) 25, as shown in FIG. 5A. Specifically, for example, an n-type impurity, such as phosphorus, is ion-implanted at energy of 20 KeV, at a dose of 2×10¹³ atoms/cm². Thus, the n-type source and/or drain portion 25 is formed in the active region 7, adjacent to the upper surface 7d of the active region 7.

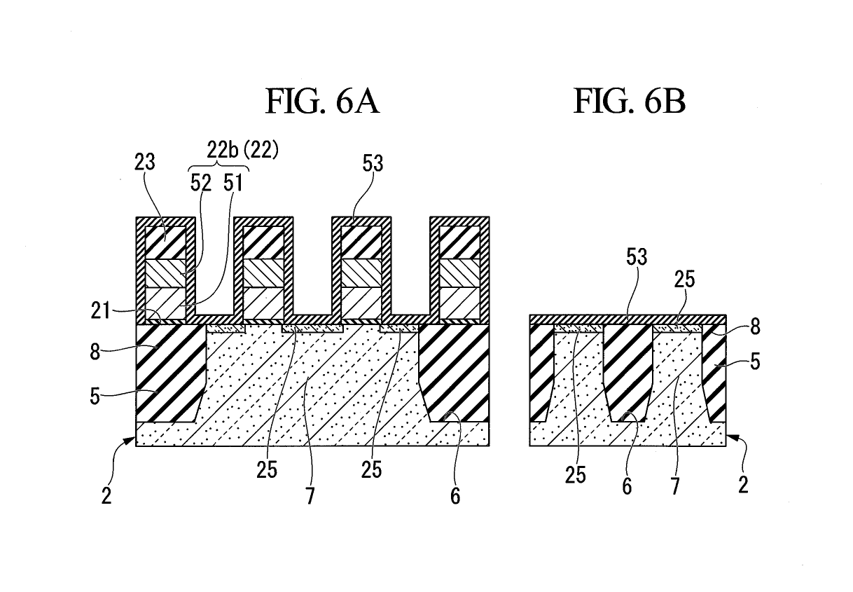

In the next process of forming a second insulating film 53, the second insulating film 53 is formed so as to cover the upper and side surfaces of the first insulating film 23, the side surface of the word wiring layer 22, and the upper surface of the semiconductor substrate 2, as shown in FIGS. 6A and 6B. The second insulating film 53 is made of, for example, a silicon nitride film. At this time, the thickness of the second insulating film 53 is preferably determined such that space between two adjacent word wiring layers 22 is not filled with the second insulating film 53.

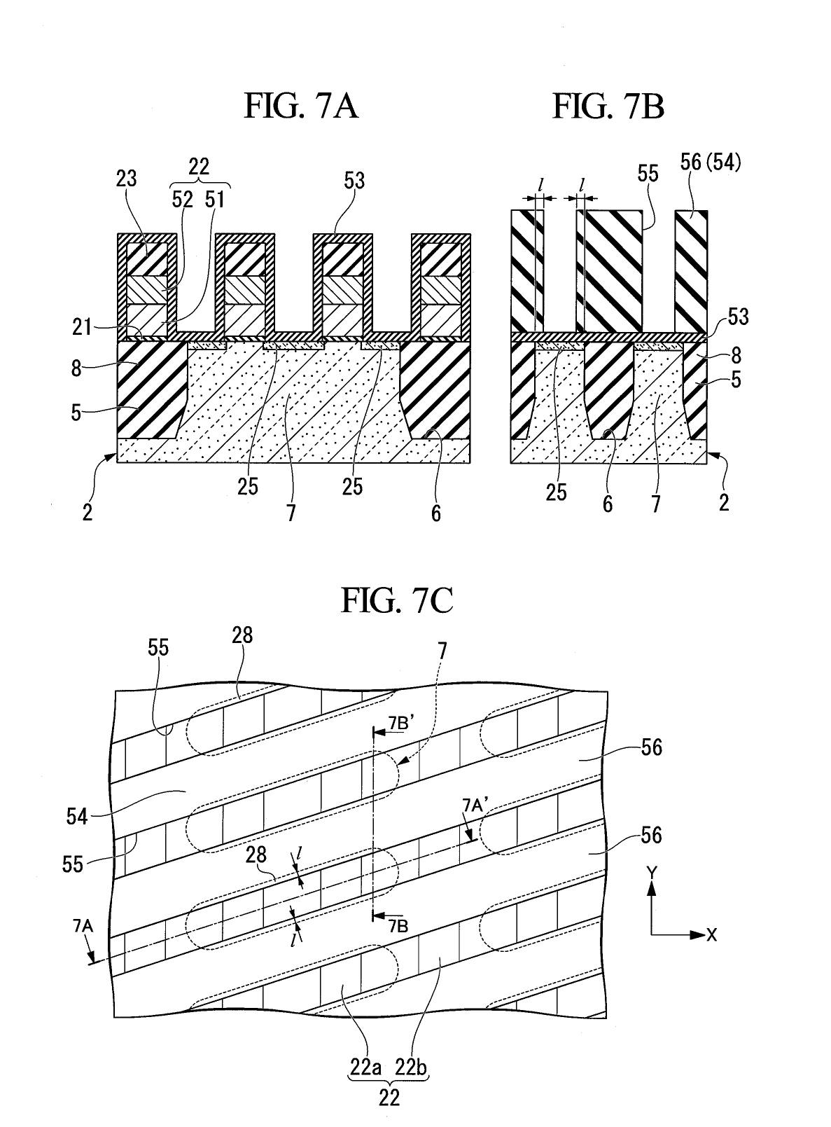

In the next process of forming the mask 54, the mask 54 made of a resist film or the like is formed by a photolithography process, as shown in FIGS. 7A to 7C. The mask 54 has a line-and-space pattern extending in the extending direction. The line-and-space pattern includes space portions 55 and line portions 56. The space portions of the mask 54 are grooves 55 exposing the active regions 7 arranged in the extending direction, the device isolation region 5 positioned between two adjacent active regions 7 in the extending direction, and the dummy word wire 22b, as shown in FIG. 7C

The width of the groove 55 in the perpendicular direction is slightly smaller than that of the active region 7 so as to form the overlap portion 28 where the mask 54 overlaps the active region 7. Specifically, the width of the overlap portion 28 in the perpendicular direction is 1.

Since the grooves 55 are positioned over the active regions 7 arranged in parallel in the perpendicular direction, the grooves 55 are arranged in parallel in the perpendicular direction.

The groove 55 achieves larger exposure margin for a photolithography process than a hole-shaped opening pattern. For this reason, the width of the groove 55 in the perpendicular direction can be small, which contributes to further miniaturization of the semiconductor device 1.

Thus, closed regions are defined by the word wiring layers 22 and the line portions 56 of the mask 54. The mask 54 and the first insulating film 23 that is formed over the word wiring layer 22 function as masks for an etching process.

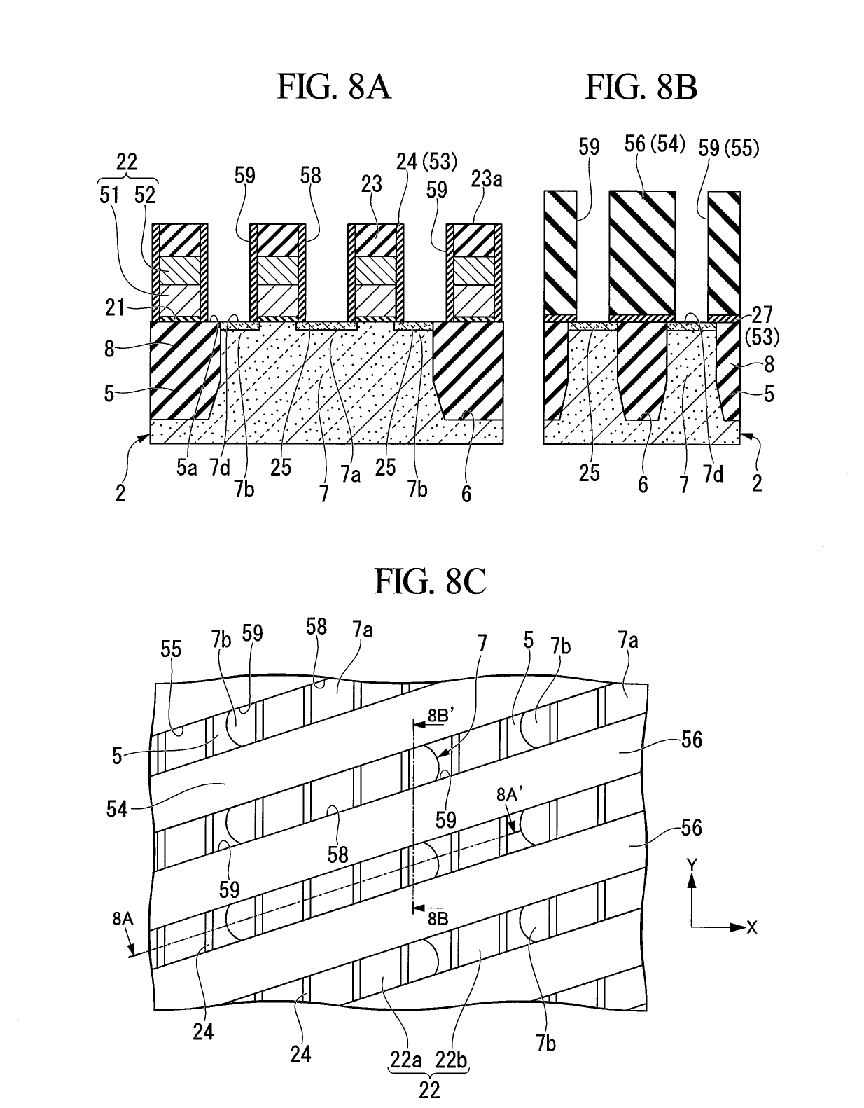

In the next process of forming the third insulating film 27, the second insulating film 53 is anisotropically dry-etched with the first insulating film 23 and the mask 54 as masks, as shown in FIGS. 8A and 8B. Consequently, an upper surface 23a of the first insulating film 23, the upper surface 7d of the active region 7, and part of the upper surface 5a of the device isolation region 5 are exposed. At this time, a remaining part of the second insulating film 53 covers side surfaces of the grooves 55 (i.e., side surfaces of the word wiring layer 22 and the first insulating film 23). The remaining part of the second insulating film 53 becomes the sidewall 24.

On the other hand, the second insulating film 53 remains under the line portions 56 of the mask 54. The remaining part of the second insulating film 53, which covers the device isolation region 5 and part of the active region 7, becomes the third insulating film 27.

Thus, in the grooves 55 of the mask 54, closed regions are defined by the line portions 56 of the masks 54 and the word wiring layers 22 with the sidewalls 24. Hereinafter, among the closed regions, a region where the active region 7a is exposed is defined as a first opening region 58, and a region where the active region 7b is exposed is defined as a second opening region 59.

In the first opening region 58, the source and/or drain portion 25 in the active region 7a is exposed. In the second opening region 59, the source and/or drain portion 25 in the active region 7b and part of the device isolation region 5 are exposed.

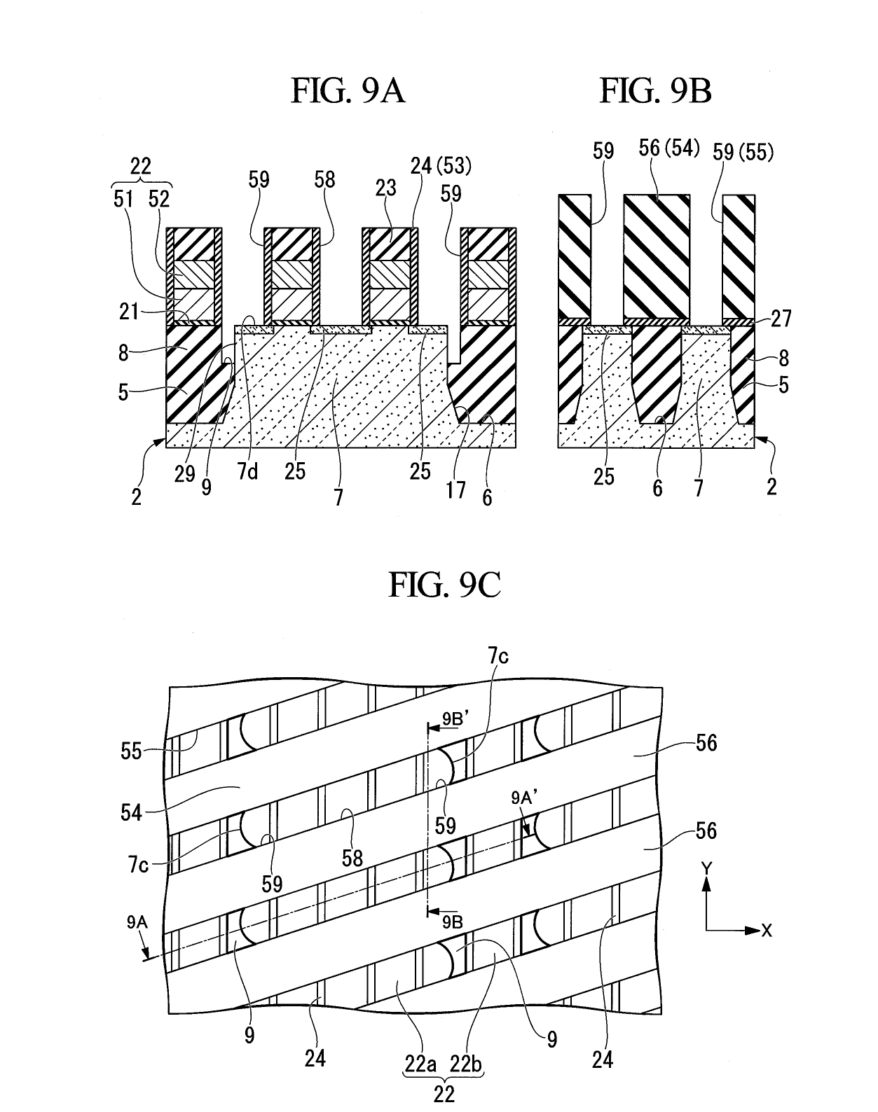

In the next process of removing part of the device isolation film 8, part of the device isolation film 8 is removed by an anisotropic dry-etching process with the mask 54, the first insulating film 23, and the sidewall 24 as masks, as shown in FIGS. 9A to 9C.

Specifically, the anisotropic dry-etching process is carried out under the condition that the etching rate of the silicon oxide film included in the device isolation film 8 is larger than those of the resist material included in the mask 54, the silicon nitride film included in the first insulating film 23 and the sidewall 24, and silicon included in the semiconductor substrate 2. Thereby, the device isolation film 8 can be selectively removed.

Consequently, the recessed portions 9 are formed in the device isolation film 8. Additionally, an upper part of the side surface of the shallow trench 6 (i.e., an upper part of the side surface 17 of the active region 7) is exposed. The exposed part of the side surface of the shallow trench 6 is defined as an exposed side surface 29.

At this time, the depth of the recessed portion 9 is adjusted by controlling the etching process, and thereby the area of the exposed side surface 29 can be adjusted. Accordingly, the etching process is carried out according to the desired exposed area of the active region 7.

As shown in FIG. 9C, part of the device isolation film 8 in the second opening region 59 is selectively removed such that the side surface 17 of the end portion 7c of the active region 7 is exposed. In other words, the recessed portion 9 is formed by removing part of the device isolation film 8 between the word wire 22a and the dummy wire 22b. Additionally, the recessed portions 9 are positioned adjacent to both end portions 7c of the active region 7. This etching process may be carried out by the same etching device sequentially after the etching process of forming the third insulating film 27.

In the next process of removing the mask 54, the mask 54 is removed by an ashing process. This removal process may be carried out after the etching of the second insulating film 53 in the process of forming the third insulating film 27. In this case, the first insulating film 23, and the third insulating film 27 to which the pattern of the mask 54 is transferred, may be used as masks for etching the device isolation film 8.

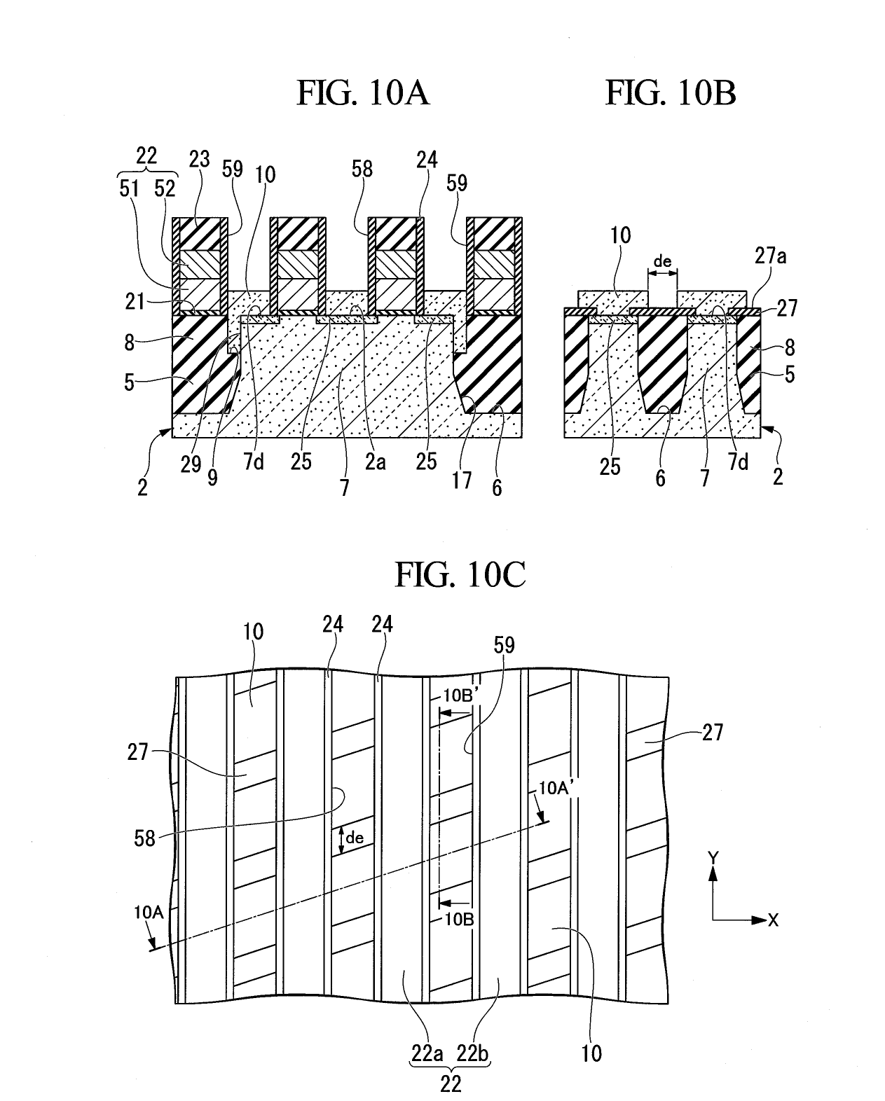

In the next process of forming the silicon film 10, the silicon film 10 is formed by a selective epitaxial growth method so as to cover the exposed upper surface (silicon surface) 7d of the active region 7 and to fill the recessed portion 9, as shown in FIGS. 10A to 10C. Specifically, the silicon film 10 is epitaxially grown from the exposed upper surface of the source and/or drain portion 25 in the first opening region 58, the exposed upper surface of the source and/or drain portion 25 in the second opening region 59, and the exposed side surface 29. A gas containing, for example, dichlorosilane and hydrochloric acid may be used for the selective epitaxial growth method.

The silicon film 10 functions as a semiconductor layer extending upward from the upper surface 7d of the active region 7. In a later process, the cell contact plug 31 is formed over the silicon film 10.

Since the structure in which the active region 7 extends upward is formed, a high-concentration impurity diffusion region can be formed, thereby enabling enhancement in driving performance of the transistor, a reduction in contact resistance of the contact plug, and application of a metal contact plug.

As shown in FIG. 10A, in the first opening region 58, the silicon film 10 grows upward from the exposed upper surface 7d of the active region 7. On the other hand, in the second opening region 59, the silicon film 10 grows upward from the exposed upper surface 7d of the active region 7 and grows laterally from the exposed side surface 29 (i.e., in the direction parallel to the upper surface 2a of the semiconductor substrate 2). Thus, the recessed portion 9 is filled with the silicon film 10.

Generally, the end portions 7c of the active region 7b are likely to be rounded and become smaller in size when the active region 7 is formed by a photolithography process. For this reason, the surface area of the active region 7b is likely to be small. With miniaturization of semiconductor devices, the surface area of the active region 7b decreases further.

Generally, selective epitaxial growth is susceptible to the state in which a natural oxide film, foreign substances, and the like are removed from a surface of a semiconductor substrate from which the epitaxial growth proceeds. For this reason, in the case of the semiconductor device of the related art, the area of the upper surface (silicon surface) of the semiconductor substrate from which epitaxial growth proceeds is small, growth of a silicon film is disturbed by a remaining natural oxide film or small foreign substances, thereby causing insufficient growth of the silicon film. Consequently, the vertical size of the grown silicon film becomes small.

On the other hand, in the case of the first embodiment of the present invention, part of the device isolation film 8 is etched so as to expose an upper part of the side surface 17 of the active region 7, thereby enabling an increase in the area of the exposed silicon surface. Accordingly, insufficient epitaxial growth of the silicon film 10 can be prevented.

Additionally, as shown in FIG. 10B, the silicon film 10 grows upward from the upper surface 7d of the active region 7. As the growth proceeds, the silicon film 10 becomes higher in level than an upper surface 27a of the third insulating film 27, and then the silicon film 10 continuously grows upward and also grows laterally along the upper surface 27a of the third insulating film 27.

Generally, selective epitaxial growth proceeds selectively from a silicon surface. For this reason, the vertical thickness of the grown silicon film is likely to become larger than the horizontal thickness thereof. Accordingly, the vertical thickness of the silicon film 10, which grows higher in level than the upper surface 27a of the third insulating film 27, is likely to become larger than the horizontal thickness thereof.

It is necessary to form the silicon film 10 such that two adjacent silicon films 10, which have grown from two adjacent active regions 7, are not shorted. In the case of FIG. 10C, the dummy word wire 22b is provided between two adjacent silicon films 10 arranged in the extending direction, thereby preventing short-circuit between the two adjacent silicon films 10.

However, there is no word wiring layer 22 between two adjacent silicon films 10 arranged in the perpendicular direction, and thereby short-circuit in the perpendicular direction cannot be prevented. For this reason, it is necessary to adjust the upper limit of the vertical thickness of the silicon film 10 so that two adjacent silicon films 10 arranged in the perpendicular direction are not shorted. For this reason, in the first embodiment, two adjacent silicon films 10 arranged in the perpendicular direction are separated in the Y-direction by the distance de.

With further miniaturization of semiconductor devices, the interval between two adjacent active regions 7 becomes smaller. For this reason, to prevent short-circuit between two adjacent active regions 7, it is necessary to further limit the vertical size of the silicon film 10 formed by epitaxial growth.

In the first embodiment, the third insulating film 27 is formed between two adjacent active regions arranged in the perpendicular direction. For this reason, while the top level of the grown silicon film 10 is lower than the top level of the third insulating film, the growth of the silicon film 10 in the horizontal direction can be prevented. Accordingly, short-circuit of the silicon films 10 in the Y-direction can be prevented compared to the case of the related art.

The third insulating film 27 and the sidewall 24 of the word wiring layer 22 are formed in the same process, and therefore an additional process is not required, thereby preventing an increase in the manufacturing cost.

In the next process of introducing an impurity, an n-type impurity, such as arsenic, is ion-implanted into the silicon film 10. The ion-implantation of an impurity into the silicon film 10 may be carried out at the same time with the epitaxial growth (i.e., insitu).

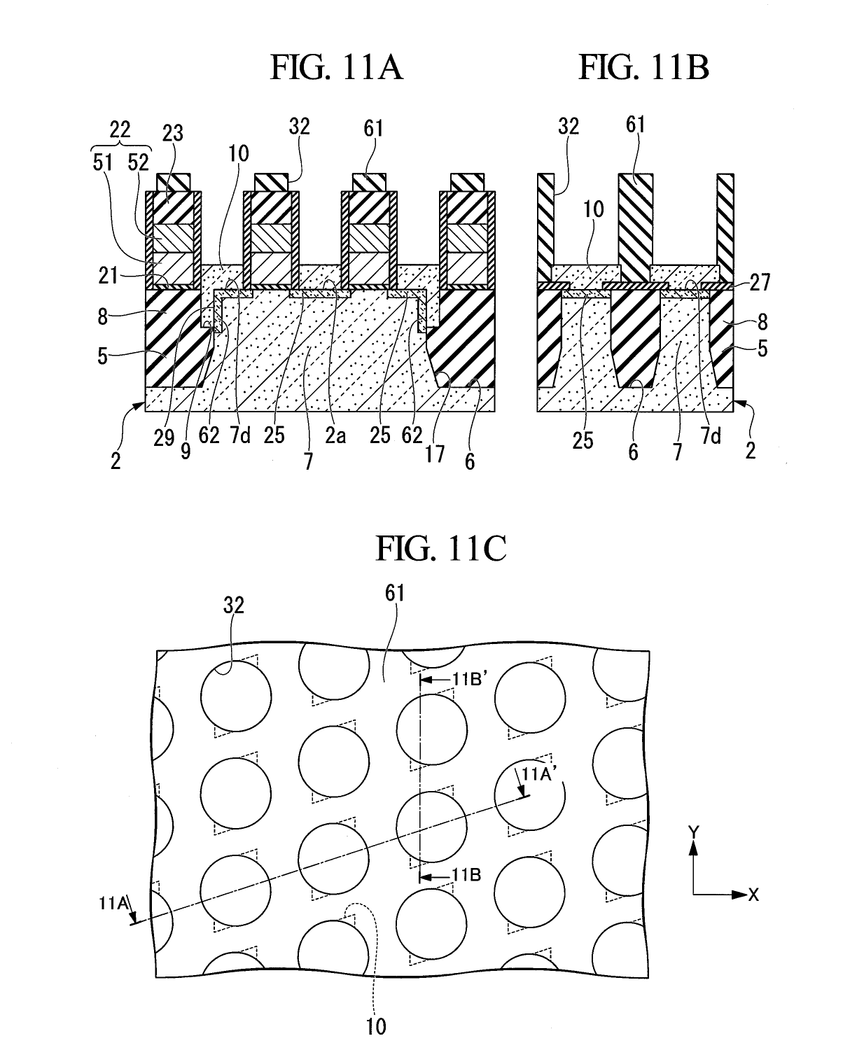

In the next process of diffusing the impurity, a first inter-layer film 61 made of a silicon oxide film or the like is formed over the semiconductor substrate 2 so as to cover the first insulating film 23, as shown in FIGS. 11A to 11C.

Then, a thermal treatment is carried out to diffuse the impurity contained in the silicon film 10 into the semiconductor substrate 2. Thus, a source and/or drain portion (impurity diffusion region) 62 is formed in the semiconductor substrate 2, adjacent to the exposed side surface 29. The source and/or drain portion 62 is coupled to the source and/or drain portion 25. This thermal treatment may be carried out in another process as long as being carried out after the process of introducing an impurity into the silicon film 10.

In the next process of forming the cell contact plug 31, a cell contact hole 32 is formed in the first inter-layer film 61 so as to expose the upper surface of the silicon film 10. In FIG. 11C, the edge of the silicon film 10, which is not exposed actually, is shown by a dashed line.

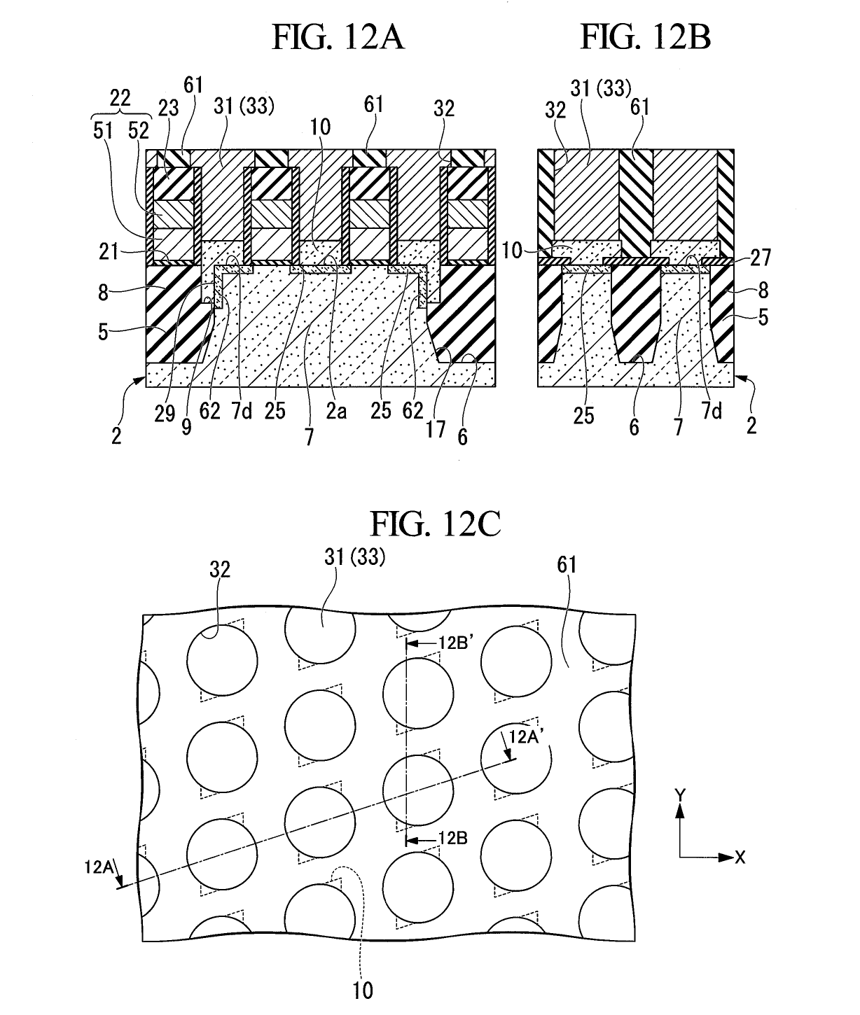

Then, the cell contact hole 32 is filled with a cell contact plug material 33, as shown in FIGS. 12A to 12C. For example, poly-crystalline silicon containing an impurity such as phosphorus (e.g., phosphorus-doped silicon) may be used as the cell contact plug material 33. However, the cell contact plug material 33 is not limited thereto. A high-melting point metal multi-layered film, which includes a titanium (Ti) film, a titanium nitride (TiN) film, and a tungsten (W) film which are sequentially deposited, may be used.

Then, the cell contact plug material 33 is partially removed by a CMP (chemical mechanical polishing) method to form the cell contact plug 31. In the first embodiment, the cell contact plug 31 is formed over the silicon film 10 that extends upward from the active region 7.

For this reason, even when a high-melting point multi-layered metal film is used as the cell contact plug material 33 to form a metal contact plug, and if a metal silicide layer is formed by a metal layer at the bottom surface of the metal contact plug reacting with the silicon layer, a high-concentrated impurity diffusion layer can be formed in the silicon film 10 so as to cover a damaged layer, thereby preventing degradation of transistor characteristics.

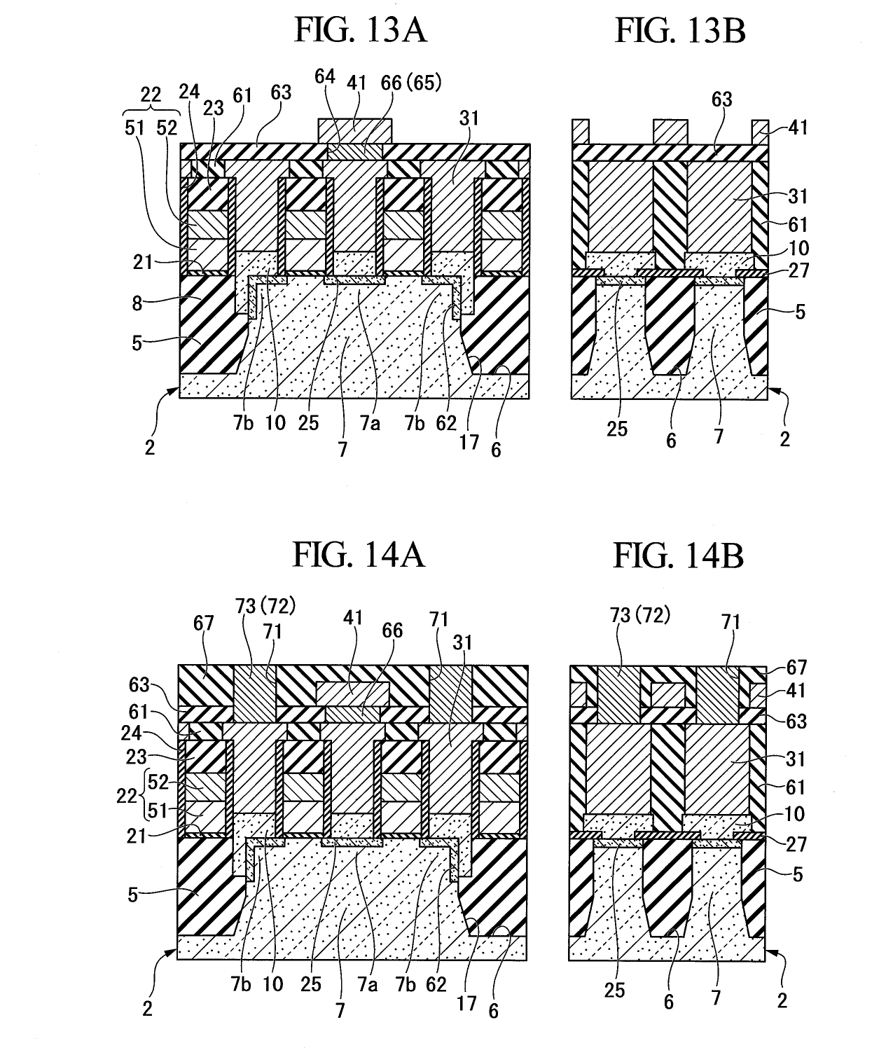

In the next process of forming the bit wire, a second inter-layer film 63 is formed over the cell contact plug 31 and the first inter-layer film 61, as shown in FIGS. 13A and 13B. The second inter-layer film 63 is made of a silicon oxide film or the like. Then, a bit-wire contact hole 64 is formed so as to expose an upper surface of the cell contact plug 31 over the active region 7a.

Then, the bit wire contact hole 64 is filled with a bit-wire contact plug material 65. As the bit wire contact plug material 65, a multi-layered film, which includes a titanium film, a titanium nitride film, and a tungsten film that are sequentially deposited, may be used.

Then, the bit-wire contact plug material 65 is partially removed by the CMP method to form the bit-wire contact plug 66. Then, the bit wire 41 to be coupled to the bit-wire contact plug 66 is formed. The bit wire 41 has a line pattern extending in the X-direction.

In the next process of forming the capacitor contact plug, a third inter-layer film 67 made of a silicon oxide film or the like is formed over the second inter-layer film 63, as shown in FIGS. 14A and 14B. Then, a capacitor contact hole 71 is formed so as to penetrate the second and third inter-layer films 63 and 67 and to expose an upper surface of the cell contact plug 31 over the active region 7b.

Then, the capacitor contact hole 71 is filled with a capacitor contact plug material 72. As the capacitor contact plug material 72, a multi-layered film, which includes a titanium film, a titanium nitride film, and a tungsten film which are deposited sequentially, may be used. Then, the capacitor contact plug material 72 is partially removed by the CMP method to form the capacitor contact plug 73.

In the next process of forming the capacitor 4, a fourth inter-layer film 74 is formed over the third inter-layer film 67, as shown in FIG. 2. Then, a capacitor contact hole 43 is formed so as to penetrate the fourth inter-layer film 74 and to expose the upper surface of the capacitor contact plug 73.

Then, the lower electrode 44 is formed so as to cover bottom and side surfaces of the capacitor contact hole 43. Then, a capacitor insulating film 45 is formed so as to cover the capacitor lower electrode 44. The capacitor insulating film 45 is made of a high dielectric film, such as a zirconium oxide (ZrO₂) film.

Then, the upper electrode 46 is formed over the capacitor insulating film 45. As materials of the lower and upper electrodes 44 and 46, for example, a metal film, such as a titanium nitride film, may be used.

Then, a fifth inter-layer film 75 made of a silicon oxide film or the like is formed over the upper electrode 46. Then, a metal wiring layer 42 is formed over the fifth inter-layer film 75. Thus, the semiconductor device 1 is complete.

According to the manufacturing method of the first embodiment, the silicon film 10 is formed so as to cover part of the side surface 17 and the upper surface 7d of the active region 7. Accordingly, a sufficient amount of the silicon film 10 can be formed over the active region 7. In the case of the manufacturing method of the related art, the silicon film is formed while only part of the upper surface of the active region is exposed. For this reason, the area of an exposed surface of the semiconductor substrate, from which the silicon film is epitaxially grown, is small. Accordingly, a sufficient amount of the silicon film cannot be formed.

On the other hand, in the case of the manufacturing method of the first embodiment, the silicon film 10 is formed while part of the upper surface 7d and the side surface 17 of the active region 7 are exposed. For this reason, the area of an exposed surface of the active region 7, from which the silicon film 10 is epitaxially grown, is larger than in the case of the related art. Accordingly, a sufficient amount of the silicon film 10 can be formed.

Additionally, the third insulating film 27 is formed over the device isolation region 5 between two adjacent active regions 7 arranged in the perpendicular direction, thereby preventing short-circuit between the two adjacent active regions 7 arranged in the perpendicular direction. Further, the third insulating film 27 can be formed simultaneously with the sidewall 24, thereby preventing an increase in the manufacturing cost.

Although the case, in which there is no misalignment of the word wiring layer 22 with respect to the device isolation region 5, has been explained in the first embodiment, the first embodiment is applicable to a case in which there is misalignment.

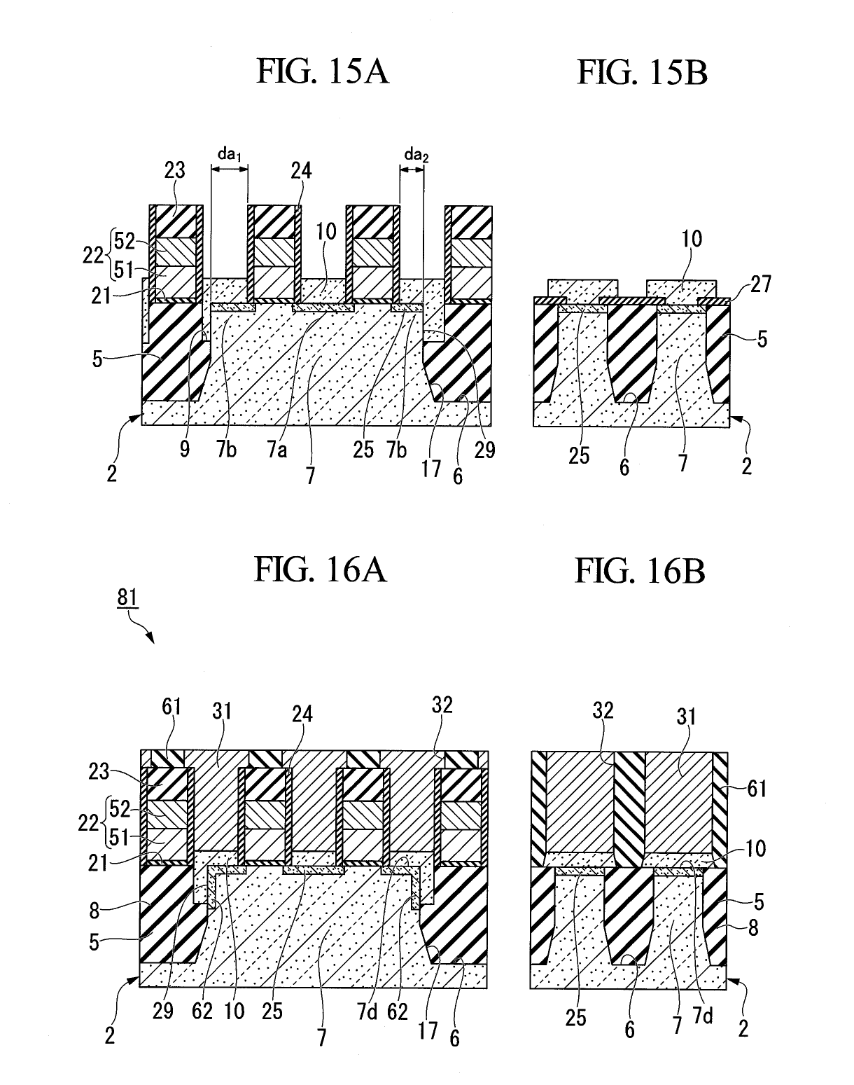

For example, in the case of FIG. 15A, the width of a portion of the silicon film 10 over the left active region 7b is defined as da₁. The width of a portion of the silicon film 10 over the right active region 7b is defined as da₂. It is assumed that da₁>da>da₂, where da defines the width of a portion of the silicon film 10 over the active region 7b when there is no misalignment (i.e., in the case of FIG. 3).

The width da₂ on the right side is much smaller than the width da. Thus, the area of the active region 7b, from which the silicon film 10 is epitaxially grown, is further decreased. Consequently, it becomes more difficult to prevent improper growth of the silicon film if the manufacturing method of the related art is used.

In the first embodiment, however, an upper part of the side surface 17 of the active region 7b is used as a basis for epitaxial growth of the silicon film 10.

Accordingly, the sufficient area of an exposed silicon surface, from which the silicon film is epitaxially grown, can be secured even if there is misalignment, thereby preventing improper epitaxial growth.

### Second Embodiment

Hereinafter, a semiconductor device 81 and a method of manufacturing the same according to a second embodiment of the present invention are explained. Like reference numerals denote like elements between the first and second embodiments.

FIGS. 16A and 16B are cross-sectional views illustrating the semiconductor device 81. The semiconductor device 81 of the second embodiment has the same structure as of the semiconductor device 1 of the first embodiment except that the third insulating film 27 of the first embodiment is not included.

Specifically, as shown in FIG. 16B, the first inter-layer film 61 is in contact with the device isolation region 5. The silicon film 10 covers the entire top surfaces of the active region 7 except for the regions of the word wires 22a and the sidewalls 24. Illustration of portions that are positioned higher in level than the first inter-layer film 61 is omitted in FIGS. 16A and 16B.

Similar to the first embodiment, the silicon film 10 is formed so as to cover not only the upper surface 7d of the active region 7, but also an upper part of the side surface 17 of the active region 7. Accordingly, the sufficient area of an exposed surface of the active region 7, from which the silicon film 10 is epitaxially grown, can be secured, thereby preventing insufficient epitaxial growth of the silicon film 10.

Since the silicon film 10 extends upward from the active region 7, a high-concentrated impurity diffusion region can be formed, thereby enabling enhancement in driving performance of the transistor, a reduction in contact resistance of the contact plug, and application of a metal contact plug.

Different from the first embodiment, the third insulating film 27 is not provided in the second embodiment. Accordingly, the area of an exposed upper surface 7d of the active region 7 can be increased compared to the first embodiment, thereby further preventing insufficient epitaxial growth of the silicon film 10 than in the case of the first embodiment.

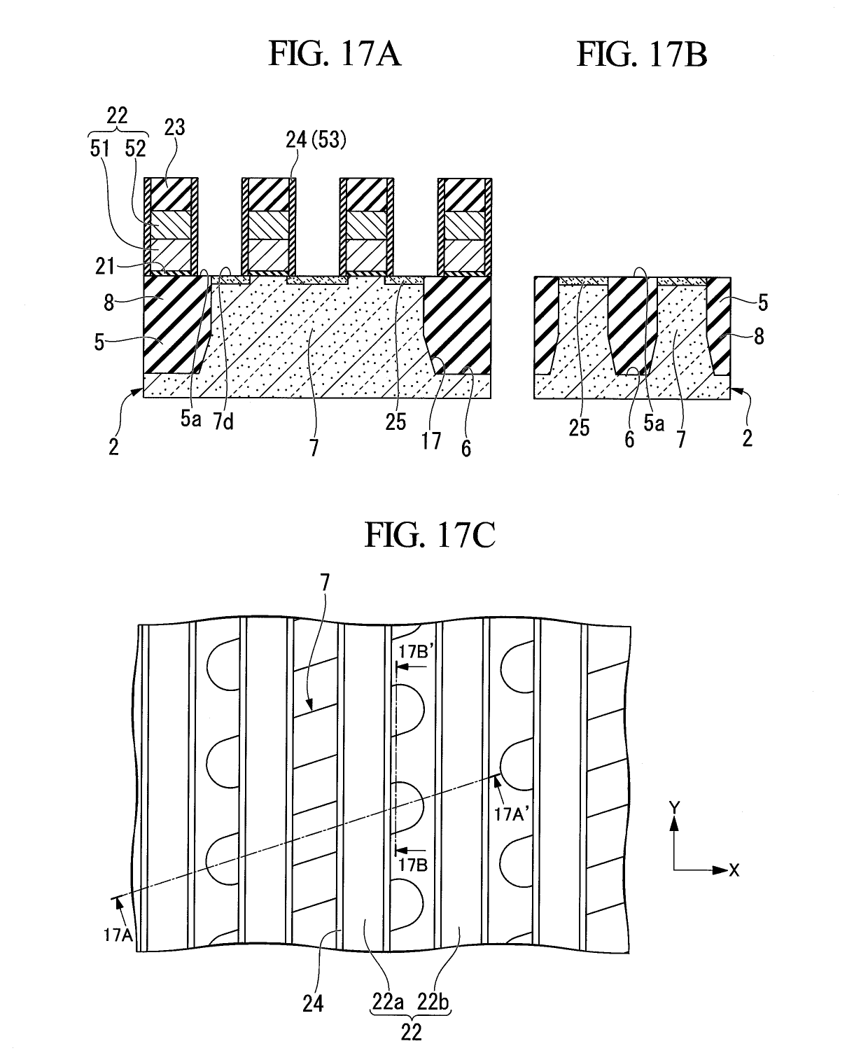

Hereinafter, a method of manufacturing the semiconductor device 81 is explained. Similar to the first embodiment, the processes up to the process of forming the second insulating film 53 are carried out as shown in FIGS. 5A to 6B. Then, the second insulating film 53 is anisotropically dry-etched without forming masks, to form the sidewall 24 as shown in FIGS. 17A to 17C. Thus, the upper surface 7d of the active region 7 and the upper surface 5a of the device isolation region 5 except for the regions of the word wiring layer 22 and the sidewall 24 are exposed.

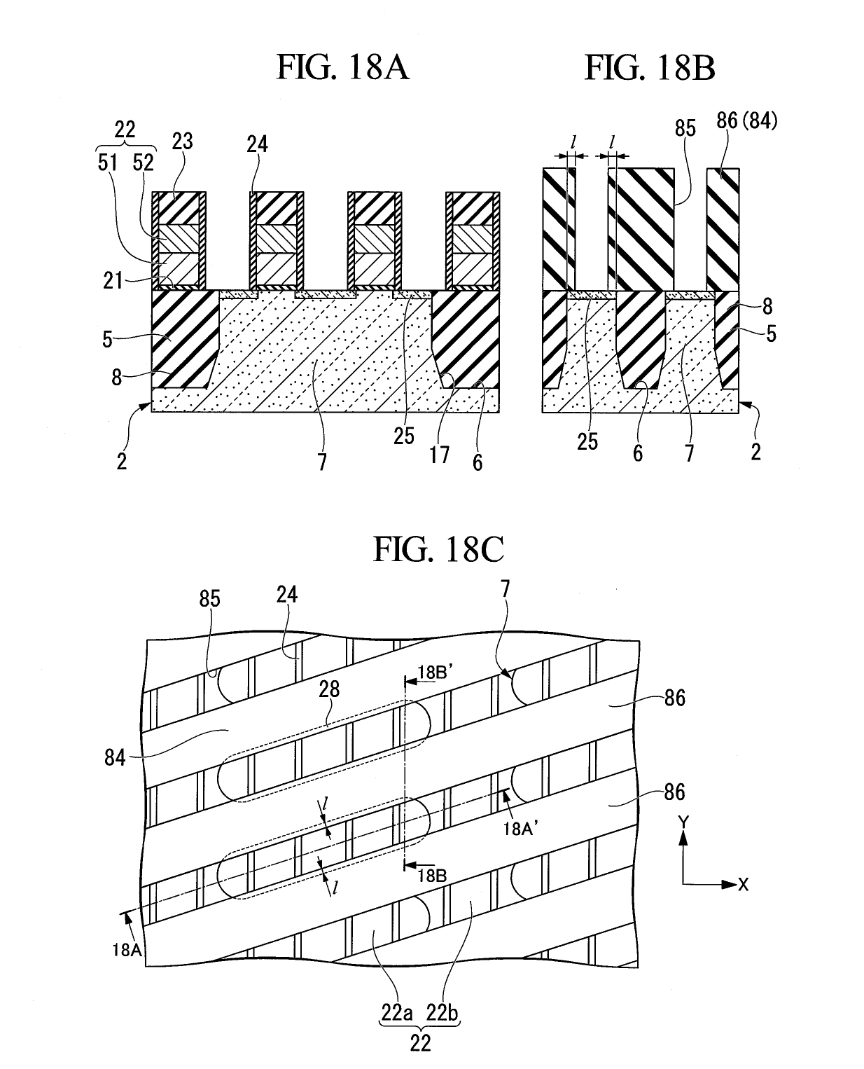

Then, a mask 84 having a similar mask pattern to that of the mask 54 of the first embodiment is formed using a photoresist film, as shown in FIGS. 18A to 18C. The mask 84 has a line-and-space pattern similar to that of the mask 54 of the first embodiment. The mask 84 has space portions (i.e., grooves) 85 and line portions 86.

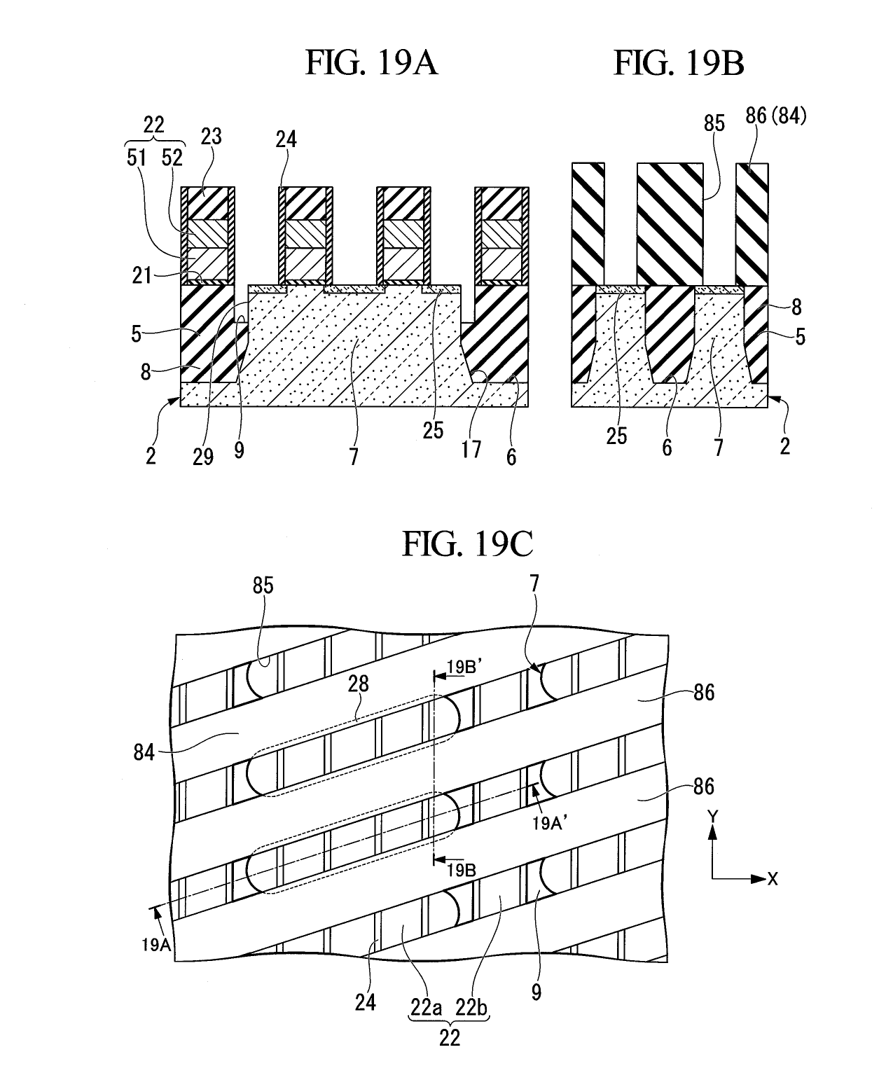

Then, the device isolation film 8 is partially removed by an anisotropic dry-etching process with the mask 84 to from the recessed portion 9, as shown in FIGS. 19A to 19C. Consequently, an upper part of the side surface (silicon surface) 17 of the active region 7, i.e., an upper part of the side surface of the shallow trench 6, is partially exposed. Thus, the exposed side surface 29 is formed.

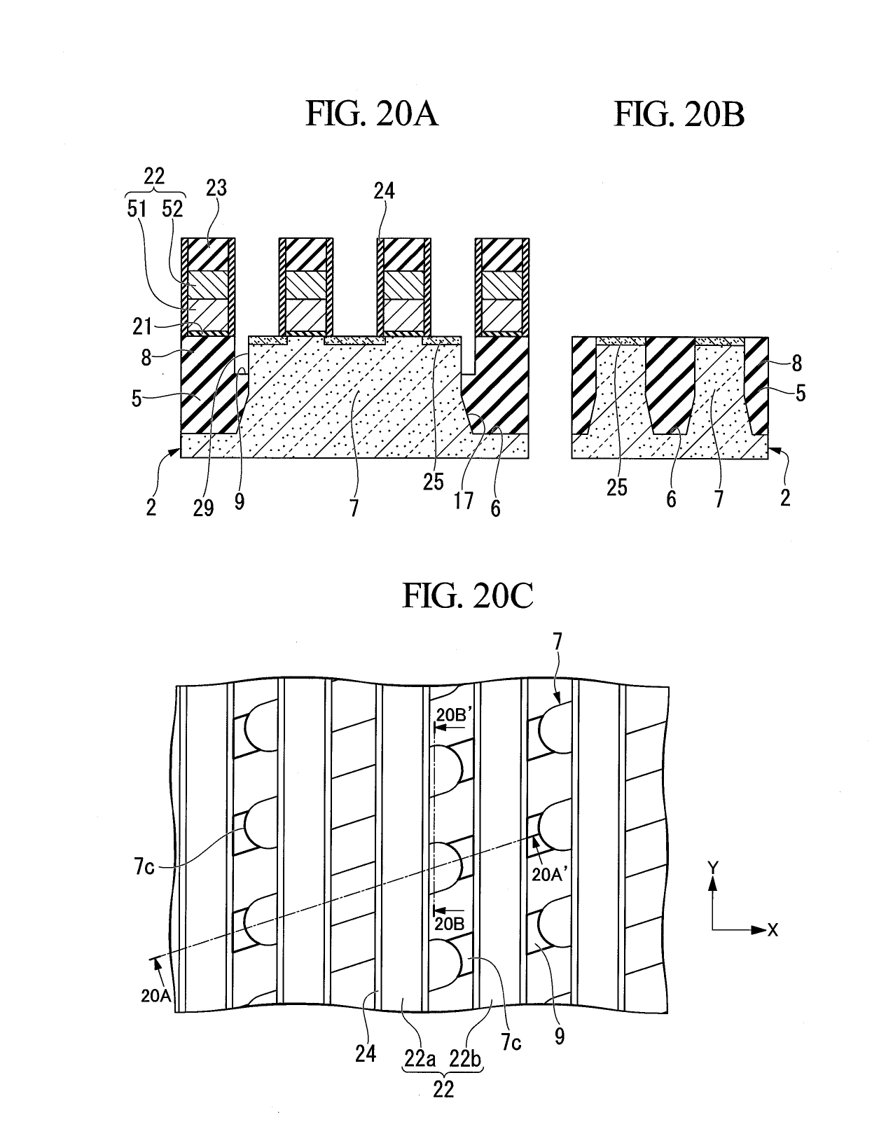

Then, the mask 84 is removed by an ashing process, as shown in FIGS. 20A to 20C. Thus, the recessed portions 9 are formed adjacent to both end portions 7c of the active region 7 in plan view, as shown in FIG. 20C.

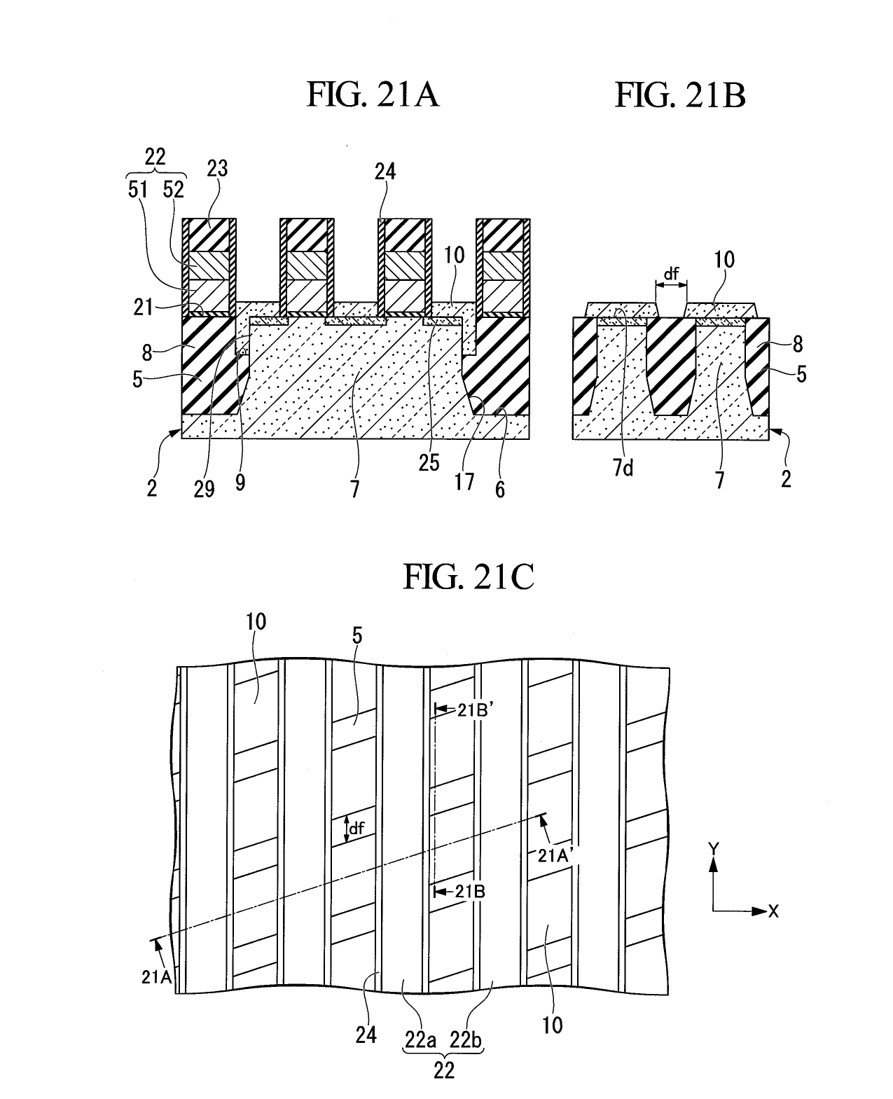

Then, the silicon film 10 is selectively formed by the epitaxial growth method so as to cover the active region 7 and fill the recessed potion 29, as shown in FIGS. 21A to 21C. In the first embodiment, the entire upper surface 7d of the active region 7 except for the regions of the word wiring layer 22 and the sidewall 24 are exposed. For this reason, the area of the exposed silicon surface, from which the silicon film 10 is epitaxially grown, is wider than in the case of the first embodiment.

In the first embodiment, to secure margin in consideration of misalignment, the third insulating film 27 is formed so as to cover the edge portions of the upper surface 7d of the active region 7. Therefore, the area of the exposed upper surface 7d of the active region 7 is small. In the second embodiment, on the other hand, since the third insulating film 27 is not formed, the area of the exposed upper surface 7d of the active region 7 is larger than that of the first embodiment.

Similar to the first embodiment, two adjacent silicon films 10 arranged in the Y-direction is distanced from each other by a distance Df in order to prevent short-circuit therebetween, as shown in FIGS. 21B and 21C.

In the second embodiment, the third insulating film 27 is not formed between two adjacent active regions 7 arranged in the perpendicular direction. For this reason, it is necessary to set the upper limit of the vertical thickness of the silicon film 10 to be smaller than in the case of the first embodiment, so as to prevent short-circuit between the two adjacent silicon films 10 arranged in the perpendicular direction, which is caused by epitaxial growth of the silicon film in the horizontal direction.

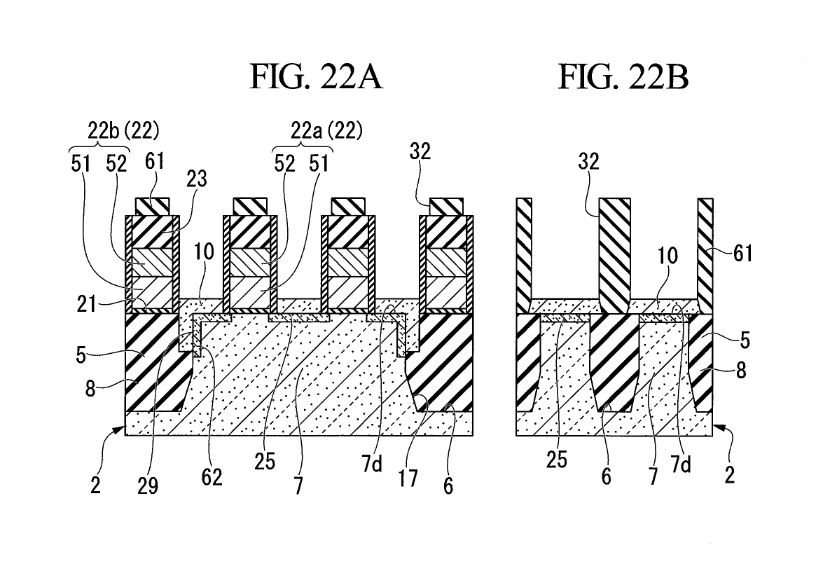

After the silicon film 10 is formed, an impurity is introduced into the silicon film 10, similarly to the first embodiment. Then, the first inter-layer 61 is formed as shown in FIGS. 22A and 22B. Then, a thermal treatment process is carried out to diffuse the impurity contained in the silicon film 10 into the semiconductor substrate 2. Thus, the source and/or drain portion 62 is formed in the semiconductor substrate 2, adjacent to the exposed side surface 29. The source and/or drain portion 62 is coupled to the source and/or drain portion 25.

Then, the cell contact hole 32, the cell contact plug 31, the capacitor 4, and the like, are formed similarly to the first embodiment. Thus, the semiconductor device 81 is complete.

According to the second embodiment, similar to the first embodiment, insufficient epitaxial growth of the silicon film 10 can be prevented even when miniaturization of semiconductor devices progresses.

Additionally, since the exposed side surface 29 is formed in the second embodiment, such a long processing time required for epitaxial growth of the silicon film 10 as in the related art is not required in the second embodiment of the present invention. For this reason, although the third insulating film 27 is not formed in the second embodiment, short-circuit of two adjacent memory cells can be prevented compared to the related art. Accordingly, a high-integrated semiconductor device 81 can be manufactured without degrading the manufacturing yield.

Although the effect of the first embodiment preventing insufficient growth of the silicon film 10 is not so great as that of the second embodiment, the effect of the first embodiment preventing short-circuit between two adjacent memory cells arranged in the perpendicular direction is greater than that of the second embodiment.

On the other hand, although the effect of the second embodiment preventing short-circuit between two adjacent memory cells arranged in the perpendicular direction is not so great as that of the first embodiment, the effect of the second embodiment preventing insufficient growth of the silicon film 10 is greater than that of the first embodiment.

Accordingly, the manufacturing method of the first embodiment or the manufacturing method of the second embodiment may be selected according to a desired layout of memory cells.

It is apparent that the present invention is not limited to the above embodiments, and may be modified and changed without departing from the scope and spirit of the invention.

For example, the layout of memory cells is not limited to the arrangement shown in FIG. 3. Another layout may be used as long as two adjacent active regions are formed. Additionally, semiconductor devices that can be formed by the manufacturing method of the present invention are not limited to the DRAM.

The present invention is applicable to the semiconductor device manufacturing industries.

As used herein, the following directional terms “forward,” “rearward,” “above,” “downward,” “vertical,” “horizontal,” “below,” and “transverse,” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percent of the modified term if this deviation would not negate the meaning of the word it modifies.

In addition, while not specifically claimed in the claim section, the application reserves the right to include in the claim section at any appropriate time the following method.

A method of manufacturing a semiconductor substrate may include, but is not limited to the following processes. A groove is formed in a semiconductor substrate. An insulating film filling the groove is formed. The insulating film is partially removed to expose a part of upper and side surfaces of the semiconductor substrate. A silicon film is epitaxially grown from the exposed part of upper and side surfaces of the semiconductor substrate.

What is claimed is:

1. A semiconductor device, comprising:
a semiconductor substrate having a groove defining a first portion of the semiconductor substrate, the first portion extending upward;
a first insulating film filling the groove, the first insulating film having a recess adjacent to a side surface of the first portion; and
a first semiconductor film contacting an upper surface and the side surface of the first portion.

2. The semiconductor device according to claim 1, further comprising:
a first wiring structure over the insulating film; and
a second wiring structure over the first portion, an upper portion of the first semiconductor film being positioned between the first and second wiring structures.

3. The semiconductor device according to claim 2, further comprising:
a first sidewall between the semiconductor film and the first wiring structure, the first sidewall insulating the first semiconductor film from the first wiring structure; and
a second sidewall between the semiconductor film and the second wiring structure, the second sidewall insulating the first semiconductor film from the second wiring structure.

4. The semiconductor device according to claim 1, wherein
the first portion has a first region containing a first impurity,
the first region is adjacent to the upper and side surfaces of the first portion, and
the first region contacts the first semiconductor film.

5. The semiconductor device according to claim 2, further comprising:
a third wiring structure over the first portion, the third wiring structure being separated from the first and second wiring structures;
a second semiconductor film contacting the upper surface of the first portion, the second semiconductor film being positioned between the second and third wiring structures.

6. The semiconductor device according to claim 5, further comprising:
a third sidewall between the second semiconductor film and the third wiring structure, the third sidewall insulating the second semiconductor film from the third wiring structure.

7. The semiconductor device according to claim 5, wherein
the first portion has a second region containing a second impurity,
the second region is adjacent to the upper surface of the first portion, and
the second region contacts the second semiconductor film.

8. The semiconductor device according to claim 2, further comprising:
a first contact plug over the first semiconductor film, the first contact plug contacting the first semiconductor film; and
a memory element over the first contact plug, the memory element being electrically coupled to the first contact plug.

9. The semiconductor device according to claim 5, further comprising:
a second contact plug over the second semiconductor film, the second contact plug contacting the second semiconductor film; and
a bit wire over the second contact plug, the bit wire being electrically coupled to the second contact plug.

10. The semiconductor device according to claim 5, wherein
the first semiconductor film comprises a first epitaxial silicon film, and
the second semiconductor film comprises a second epitaxial silicon film

11. The semiconductor device according to claim 1, wherein
the first portion extends in a first direction in plan view;
the first wiring structure extends in a second direction different from the first direction in plan view, and
the second wiring structure extends in the second direction in plan view.

12. The semiconductor device according to claim 11, wherein
the first wiring structure has a first horizontal size measured in a third direction perpendicular to the second direction,
the second wiring structure has a second horizontal size measured in the third direction,
the first portion has a third horizontal size measured in a fourth direction perpendicular to the first direction, and
a distance between the first and second wiring structures measured in the third direction, and the first to third horizontal sizes are substantially equal.

13. The semiconductor device according to claim 12, further comprising:
a third wiring structure over the first portion and the first insulating film, the third wiring structure extending in the second direction, the third wiring structure being separated from the first and second wiring structures, and the first portion having a first sub-portion between the second and third wiring structures,
wherein the first sub-portion has a fourth horizontal size measured in the first direction, and
the first to fourth horizontal sizes are substantially equal.

14. The semiconductor device according to claim 5, wherein
the semiconductor substrate has a second portion defined by the groove,
the second portion extends upward,
the second portion is separated from the first portion and the first wiring structure,
the second and third wiring structures cross the first and second portions in plan view,
the first insulating film has a first portion between the first and second portions of the semiconductor substrate and between the second and third wiring structures, and
the semiconductor device further comprising:
a second insulating film covering the first portion of the first insulating film, the second insulating film partially overlap the first and second portions of the semiconductor substrate in plan view.

15. A semiconductor device comprising:
a semiconductor substrate having a first portion extending upward;
a gate electrode structure over the first portion;
a first semiconductor film adjacent to the gate electrode, the first semiconductor film contacting an upper surface of the first portion;
a second semiconductor film adjacent to the gate electrode, the first semiconductor film being separated from the second semiconductor film, and the second semiconductor film contacting the upper surface and a side surface of the first portion.

16. The semiconductor device according to claim 15, wherein
the first semiconductor film comprises a first epitaxial silicon film, and
the second semiconductor film comprises a second epitaxial silicon film.

17. The semiconductor device according to claim 15, wherein
the first portion has first and second regions containing first and second impurities, respectively,
the first region is adjacent to the upper surface of the first portion,
the second region is adjacent to the upper and side surfaces of the first portion,
the first region contacts the first semiconductor film, and
the second region contacts the second semiconductor film.

18. A semiconductor device comprising:
a semiconductor substrate having a first portion extending upward;
an insulating film adjacent to the first portion, a top level of the insulating film being substantially equal to a top level of the first portion, and the insulating film having a recess adjacent to a side surface of the first portion;
a wiring structure over the insulating film, the recess being between the first portion and the insulating film in plan view;
a semiconductor film adjacent to the wiring structure, the semiconductor film contacting an upper surface and the side surface of the first portion, and the semiconductor film filling the recess.

19. The semiconductor substrate according to claim 18, wherein the semiconductor film comprises an epitaxial silicon film.

20. The semiconductor substrate according to claim 18, wherein
the first portion has a first region containing an impurity,
the first portion is adjacent to the upper and side surfaces of the first portion, and
the first portion contacts the semiconductor film.
